(19) United States
(12) Patent Application Publication
(10) Pub. No.: US 2005/0006791 A1
(43) Pub. Date: Jan. 13, 2005

(54) Semiconductor device, manufacturing method thereof, electronic device, electronic equipment

(76) Inventor: Hideki Yuzawa, Iida-shi (JP)

Correspondence Address: HARNESS, DICKEY & PIERCE, P.L.C., P.O. BOX 828, BLOOMFIELD HILLS, MI, 48303, US

(21) Appl. No.: 10/848,816

(22) Filed: May 18, 2004

(30) Foreign Application Priority Data
May 19, 2003 (JP) 2003-140591

(51) Int. Cl. H01L 23/48

(52) U.S. Cl. 257/780

(57) ABSTRACT

A pattern of projecting electrodes is provided. In the pattern, first projected electrodes in a first row and second projected electrodes in a second row are arranged in an offset or zigzag. A bottom width of the second projected electrodes is smaller than a bottom width of the first projected electrodes and a bottom length of the second projected electrodes is longer than a bottom length of the first projected electrodes.

### RELATED APPLICATIONS

This applications claims priority to Japanese Patent Application No. 2003-140591 filed May 19, 2003 which is hereby expressly incorporated by reference herein in its entirety.

### BACKGROUND

1. Field of the Invention

The present invention relates to a semiconductor device and manufacturing method thereof, to an electronic device, an electronic component and especially adequate for flip-chip mounting applications.

2. Description of the Related Art

As for a conventional semiconductor device, for example, as disclosed in Japanese Unexamined Patent Application Publication No. 2000-269611, a method fro mounting a semiconductor chip on a wiring board by bonding a projected electrode on a connecting terminal formed on the wiring board is introduced.

FIG. 4(a) is a plan view showing a conventional layout method of connecting terminals and projected electrodes. FIG. 4(b) is a sectional view showing a structure of a semiconductor chip mounted on a wiring board.

In FIGS. 4(a) and (b), a wiring portion 42′ and a connecting terminal 42 connected to the wiring portion 42′ are formed on a wiring board 41. A rectangular shaped projected electrode 44 is disposed on a semiconductor chip 43. Here, the connecting terminal 42 and the projected electrode 44 may be provided in an offset or zigzag arrangement as shown in FIG. 4(a) for example. The semiconductor chip 43 is subjected to face-down bonding on the wiring board 41 by bonding of the projected electrode 44 disposed on the semiconductor chip 43 with the connecting terminal 42. Then, a surface of the semiconductor chip 43 may be sealed with a sealing resin filled interstices between the semiconductor chip 43 and the wiring board 41.

Along with a miniaturization of the circuit pattern, the wiring portion 42′ having a fine pitch makes the clearance D3 between the wiring portion 42′ and a projected electrode 44′ adjacent to the wiring portion 42′ narrow. Therefore, higher accuracy is required for a mounting position of the semiconductor chip 43 so that it restricts the fine pitch application for the wiring portion 42′.

In view of this, the invention aims to provide a semiconductor device, an electronic device, an electronic equipment that enable the accuracy required for a mounting position of a semiconductor chip to relax or loosen while being capable of applying the fine pitch to the wiring portion and a manufacturing method of the semiconductor device.

### SUMMARY

In order to solve the above-mentioned problem, a semiconductor device of an aspect of the invention includes a semiconductor chip, a first projected electrode array projected from and disposed on the surface of the semiconductor chip, including a plurality of first projected electrodes each having a first center, being disposed on a first line linking the first centers and a second projected electrode array projected from and disposed on the surface of the semiconductor chip, including a plurality of a second projected electrodes each having a second center, being disposed on a second line linking the second centers. The first line and the second line are spaced apart in a direction perpendicular to the first and the second line. A width of the first projected electrode is smaller than a width of the second projected electrode and a length of the first projected electrode is longer than a length of the second projected electrode.

Accordingly, it is possible to widen the width of the projected electrode in the first row so as to stably connect the projected electrode in the first row to the connecting terminal. Also, it is possible to shorten the width of the projected electrode in the second row so as to widen a clearance between the wiring portion adjacent to the projected electrode in the second row and the projected electrode in the second row. Thus, it enables the accuracy required for a mounting position of the semiconductor chip to loosen while being capable of applying the fine pitch to the wiring portion. As a result, it is possible to enhance applications of the fine pitch pattern for the wiring portion while suppressing extra burdens in a mounting process.

Also, according to a semiconductor device of an aspect of the invention, the first projected electrode and the second projected electrode are substantially equal in area of a surface facing a wiring board.

This makes it possible to uniformly apply a load to the first and the second projected electrode even if the first and the second projected electrode are different in width and length. This is capable of preventing a passivation film under the projected electrode from being damaged. Moreover, this enables the projected electrode to be free from a peeling during processing such as the semiconductor chip mounting process because it is possible to render a bonding strength of the projected electrode uniform.

Also, according to a semiconductor device of an aspect of the invention, a wiring board includes a wiring pattern on which the semiconductor chip is mounted, the wiring pattern being connected to the first and the second projected electrode.

This makes it possible to mount the semiconductor chip on the wiring board while loosening a placement accuracy required in the semiconductor chip mounting process, even if a fine pitch wiring pattern is applied to the wiring board.

Also, according to a semiconductor device of an aspect of the invention, a resin layer may be provided between the semiconductor chip and the wiring board.

This makes it possible to stably mount the semiconductor chip on a circuit board while suppressing a temperature increase during a bonding process of the projected electrode, even if the fine pitch pattern is applied to the wiring portion of the circuit board.

Also, an electronic device of an aspect of the invention includes an electronic component, a first projected electrode array projected from and disposed on a surface of the electronic component, including a plurality of first projected electrodes each having a first center, being disposed on a first line linking the first centers and a second projected electrode array projected from and disposed on the surface of the electronic device, including a plurality of a second projected electrodes each having a second center, being disposed on a second line linking the second centers. The first line and the second line are spaced apart in a direction perpendicular to the first line and the second line (laterally spaced apart). A width of the first projected electrode is smaller than a width of the second projected electrode and a length of the first projected electrode is longer than a length of the second projected electrode. Thus, the lines can be parallel and the first projected electrodes and the second projected electrodes or orthogonally oriented relative to one another and generally rectangularly or ellipsoidally shaped.

This makes it possible to stably bond the first projected electrode on the wiring pattern and to widen a clearance between the wirings on which the second projected electrode bonds. As a result, it is possible to loosen the placement accuracy required in an electronic component mounting process while applying the fine pitch to the wiring in the wiring pattern.

Also, electronic equipment of an aspect of the invention includes a semiconductor chip, a wiring board including a wiring pattern electrically connected to the semiconductor chip, an electronic component electrically connected to the semiconductor chip through the wiring board, a first projected electrode array disposed between the semiconductor chip and the wiring board, including a plurality of first projected electrodes each having a first center, being disposed on a first line linking the first centers; and a second projected electrode array disposed between the semiconductor chip and the wiring board, including a plurality of second projected electrodes each having a second center, being disposed on a second line linking the second centers. The first line and the second line are spaced apart in a direction perpendicular to the first line and the second line. A width of the first projected electrode is smaller than a width of the second projected electrode and a length of the first projected electrode is longer than a length of the second projected electrode.

This makes it possible to loosen the placement accuracy required in the semiconductor chip mounting process while enabling the fine pitch to be applied to the wiring pattern. As a result, it is possible to provide electronic equipment that is lightweight and compact size.

Also, a method of manufacturing a semiconductor device of an aspect of the invention including a semiconductor chip, a first and a second projected electrode array projected from and disposed on the semiconductor chip comprises:
a step of providing the first projected electrode array including a plurality of first projected electrodes each having a first center, being disposed on a first line linking the first centers;
a step of providing the second projected electrode array including a plurality of second projected electrodes each having a second center, being disposed on a second line linking the second centers such that a width of the first projected electrode is smaller than a width of the second projected electrode and a length of the first projected electrode is longer than a length of the second projected electrode;
a step of mounting the semiconductor chip on a wiring board where a wiring pattern is disposed through the first and the second projected electrode array; and
a step of an electrically connecting the wiring pattern to the first and the second projected electrode arrays.

This makes it possible to loosen the placement accuracy required in the semiconductor chip mounting process, even if the fine pitch pattern is applied to the wiring pattern of the wiring board. As a result, it is possible to mount the semiconductor chip on the circuit board while suppressing extra burdens in the manufacturing processes.

### BRIEF DESCRIPTION OF THE DRAWINGS

FIGS. 1(a) and (b) are diagrams showing a construction of a semiconductor device of a first embodiment of the invention.

FIGS. 2(a)-(c) are sectional views showing a method for manufacturing the semiconductor device illustrated in the FIG. 1.

FIGS. 3(a) and (b) are diagrams showing a construction of a liquid crystal module of a second embodiment of the invention.

FIGS. 4(a) and (b) are diagrams showing a construction of a conventional semiconductor device.

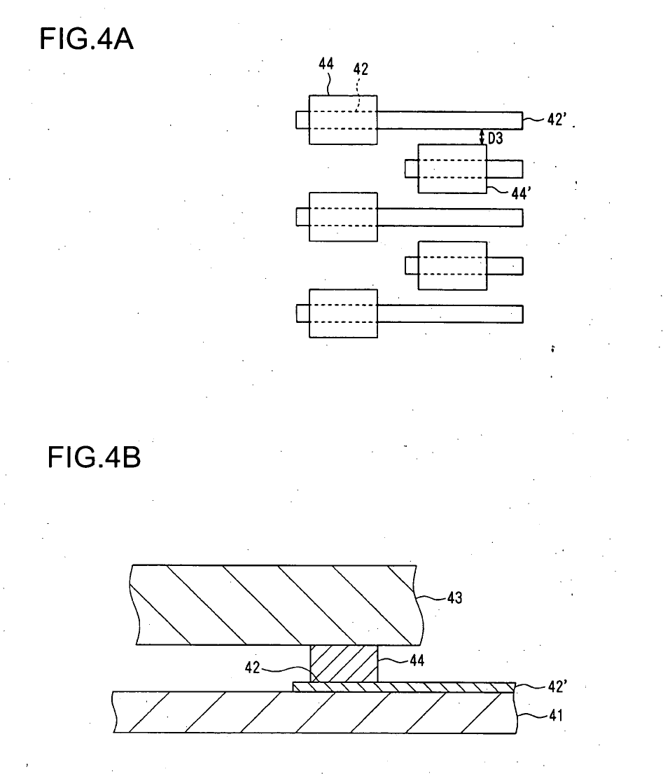

### DETAILED DESCRIPTION

The semiconductor device, the electronic device and the manufacturing method thereof according to the invention will now be described by referring to the accompanying drawings.

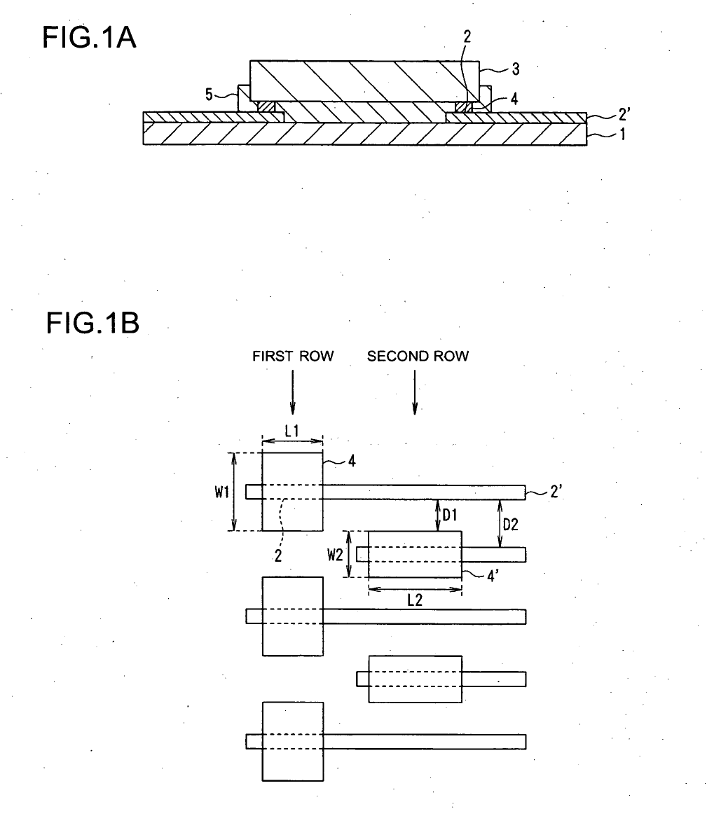

FIG. 1 (a) is a sectional view showing a structure of a semiconductor device of a first embodiment of the invention. FIG. 1 (b) is a plan view showing a formation of a connecting terminal and a projected electrode of the first embodiment of the invention.

In FIGS. 1(a) and (b), a wiring portion 2′ and a connecting terminal 2 connected to the wiring portion 2′ are formed on a wiring board 1. A projected electrode 4 is disposed on a semiconductor chip 3. Here, the connecting terminal 2 and the projected electrode 4 are able to be provided in a zigzag arrangement as shown in FIG. 1(b) for example. The semiconductor chip 3 is mounted on the wiring board 1 with ACF (Anisotropic Conductive Film) connection in which the projected terminal 4 connects onto the connecting terminal 2 through an anisotropic conductive film 5. It is capable of providing ACP (Anisotropic Conductive Paste), an electrical insulating adhesive, an electrical insulating resin and so forth instead of the ACF. Here, a projected electrode 4 in a first row and a projected electrode 4′ in a second row are provided in an offset or zigzag arrangement. A bottom width W2 of the projected electrode 4′ in the second row can be smaller than a bottom width W1 of the projected electrode 4 in the first row and a bottom length L2 of the projected electrode 4′ in the second row is longer than a bottom length L1 of the projected electrode 4 in the first row. The projected electrode 4 in the first row and the projected electrode 4′ in the second row are arranged along at least one of a long edge and a short edge of the semiconductor chip 3 so as not to be overlapped in an array direction of each projected electrode 4, 4′. Here, in a zigzag arrangement, a first projected electrode array included a first projected electrode having a first center is disposed on a first line linking the first centers and a second projected electrode array included a second projected electrode having a second center is disposed on a second line linking the second centers. Meanwhile, the first line and second line are spaced apart in a direction perpendicular to the first line and the second line (they are laterally spaced apart).

Accordingly, this makes it possible to widen the width W1 of the projected electrode 4 in the first row so as to stably connect the projected electrode 4 in the first row to the connecting terminal 2′. It is also possible to shorten the width W2 of the projected electrode 4′ in the second row so as to widen the clearance D1 between the projected electrode 4′ in the second row and the wiring portion 2′ adjacent to the projected electrode 4′ in the second row. Therefore, even in the case where the clearance D2 between the wiring portions 2′ is shortened, it is possible to secure the clearance D1 between the projected electrode 4′ in the second row and the wiring portion 2′ adjacent to the projected electrode 4′ in the second row. Consequently, it enables the accuracy required for a mounting position of the semiconductor chip 3 to loosen while being capable of applying the fine pitch to the wiring portion 2′.

It is preferable that the area of the bottom of the projected electrode 4 in the first row is substantially equal to that of the projected electrode 4′ in the second row. This makes it possible to equalize a plurality of areas in which conductive particles included in the anisotropic conductive film 5 are trapped so as to carry out stable ACF connection while being capable of applying the fine pitch to the wiring portion 2′, even in an arrangement in which the bottom width W2 of the projected electrode 4′ in the second row is smaller than the bottom width W1 of the projected electrode 4 in the first row and the bottom length L2 of the projected electrode 4′ in the second row is longer than the bottom width L1 of the projected electrode 4 in the first row.

As for the projected electrode 4, for example, it is possible to employ an Au (gold) bump, a solder coated Cu (copper) bump or Ni (nickel) bump and a solder ball. Examples of the wiring portion 2′ and connecting terminal 2 include a copper foil pattern. Examples of the wiring board 1 include a film substrate, a glass substrate. In the above-mentioned embodiment, a method that the semiconductor chip 3 is mounted on the wiring board 1 with ACF connection was described. Alternatively, an adhesive connection, for example, NCF (Nonconductive Film), and metal bonding, for example, a solder bonding or an alloy bonding and so forth are applicable.

While this invention was explained by using the semiconductor chip 3, the application of the invention is not limited to this embodiment. An electronic element may replace the semiconductor chip 3. Examples of the electronic element include a capacitor, a resister, and so forth.

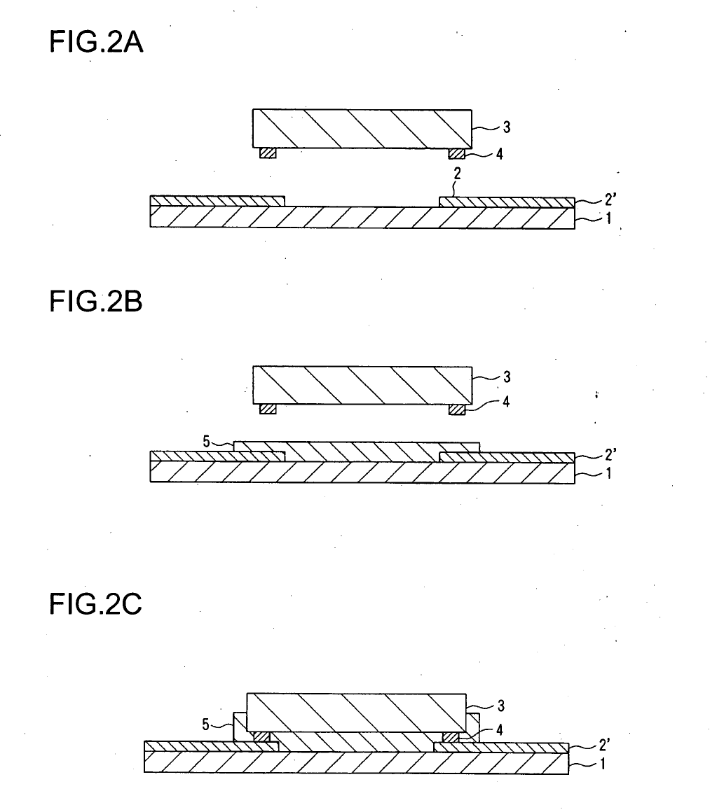

FIGS. 2(a)-(c) are sectional views showing a method for manufacturing the semiconductor device shown in FIG. 1.

In FIG. 2 (a), copper foil placed on the wiring board 1 is patterned to form the connecting terminal 2 and the wiring portion 2′.

Then, as shown in FIG. 2(b), the anisotropic conductive film 5 is attached on the wiring board 1 on which the connecting terminal 2 is formed. The semiconductor chip 3 is aligned such that the projected electrode 4 is placed on the connecting terminal 2.

Then, as shown in FIG. 2(c), load is applied on the semiconductor chip 3 with an arrangement where the projected electrode 4 is placed on the connecting terminal 2. As a result, the projected electrode 4 is connected to the connection terminal 2 with ACF connection through the anisotropic conductive film 5.

Accordingly, even if the fine pitch is applied to the wiring portion 2 of a circuit board, it is possible to loosen the accuracy required for the mounting position of the semiconductor chip. As a result it is possible to mount the semiconductor chip 3 on the circuit board while suppressing extra burdens in manufacturing processes.

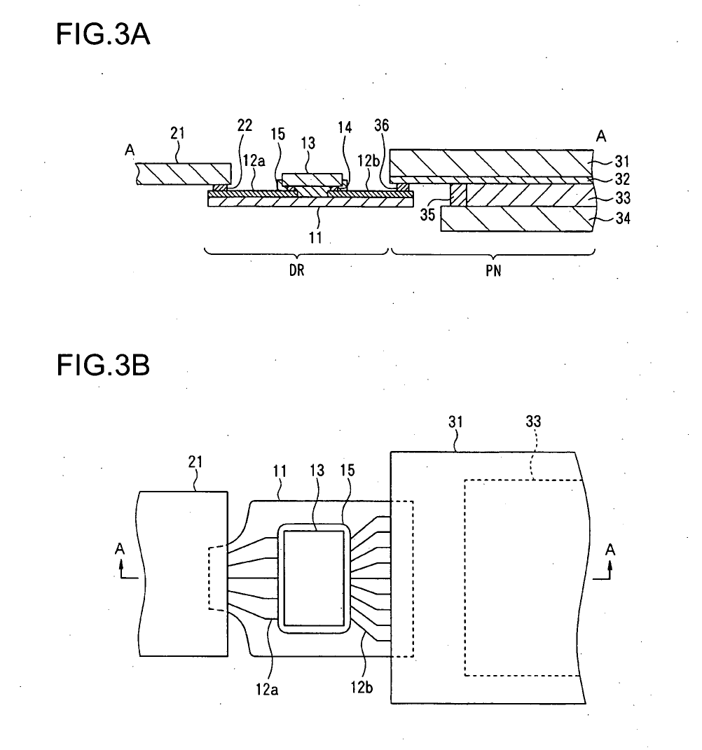

FIG. 3 (a) is a cross-sectional view taken along line A-A of FIG. 3 (b). FIG. 3 (b) is a plan view shown a rough structure of a liquid crystal module of a second embodiment of the invention.

In FIGS. 3(a) and (b), a liquid crystal module includes a liquid crystal panel PN and a liquid crystal driver DR to drive the liquid crystal panel PN. The liquid crystal driver DR includes the semiconductor chip 13 in which driving circuits and so forth are formed. The semiconductor chip 13 is mounted on the wiring board 11 through the anisotropic conductive film 5.

The liquid crystal panel PN includes a glass substrate 31, 34. A transparent electrode 32 such as ITO is formed on the glass substrate 31. A liquid crystal layer 33 is filled between the glass substrate 31 on which the transparent electrode 32 is formed and the glass substrate 34 and is sealed with a sealing member 35.

The wiring portion 12a, 12b are formed on the wiring board 11. An outer lead of the wiring portion 12a is connected to a printed wiring board 21 with a connecting terminal 22 such as ACF. An outer lead of the wiring portion 12b is connected to the transparent electrode 32 with a connecting terminal 36 such as ACF.

Each inner lead of the wiring portion 12a, 12b, for example, is connected to the projected electrode 14 included in the semiconductor chip 13 with ACF connection through the anisotropic conductive film 5. Here, the inner lead of the wiring portion 12a, 12b and the projected electrode 14 can be arranged in the zigzag as shown in FIG. 1(b) for example. Also, it is possible that the projected electrode 14 in the second row is arrayed on the semiconductor chip 13 such that its width and length is respectively smaller and longer than that corresponding to the projected electrode 14 in the first row provided in the zigzag arrangement on the semiconductor chip 13 without overlapping the projected electrode 14 in the first row in the array direction. Further, the area of the bottom of the projected electrode 14 in the first row substantially can be equal to that of the second row.

Accordingly, this makes it possible to stably connect the projected electrode 14 in the first row provided in the zigzag arrangement to the inner lead of the wiring portion 12a, 12b. Also, it is possible to widen the clearance between the projected electrode 14 in the second row and the wiring portion 12a, 12b adjacent to the projected electrodel4 in the second row. Consequently, it enables the accuracy required for the mounting position of the semiconductor chip 3 to be relaxed or loosen while being capable of applying the fine pitch to the wiring portion 12a, 12b. This makes it possible to equalize a plurality of areas in which conductive particles included in the anisotropic conductive film 5 are trapped so as to carry out ACF connection stably while being capable of applying a fine pitch to the wiring portion 12a, 12b, even in an offset or zigzag arrangement in which the width and length of the bottom of the projected electrode 14 in the second row is respectively smaller and longer than that corresponding to the projected electrode 14 in the first row.

1. A semiconductor device, comprising:
a semiconductor chip;
a first projected electrode array projecting from and disposed on a surface of the semiconductor chip, the first projected electrode array including a plurality of first projected electrodes each having a first center disposed on a first line linking the first centers; and
a second projected electrode array projecting from and disposed on the surface of the semiconductor chip, the second projected electrode array including a plurality of a second projected electrodes each having a second center disposed on a second line linking the second centers, wherein:
the first line and the second line are laterally spaced apart;
a width of each first projected electrode is smaller than a width of each second projected electrode; and
a length of each first projected electrode is longer than a length of each second projected electrode.

2. The semiconductor device according to claim 1, wherein each first projected electrode and each second projected electrode are substantially equal to each in a surface area facing a wiring board.

3. The semiconductor device according to claim 1, further comprising:
a wiring board on which the semiconductor chip is mounted; and
a wiring pattern connected to the first and the second projected electrodes and disposed on the wiring board.

4. The semiconductor device according to claim 3, wherein a resin layer is provided between the semiconductor chip and the wiring board.

5. An electronic device comprising:
an electronic component;
a first projected electrode array projecting from and disposed on a surface of the electronic component, the first projected electrode array including a plurality of first projected electrodes each having a first center disposed on a first line linking the first centers; and
a second projected electrode array projected from and disposed on the surface of the electronic component, the second projected electrode array including a plurality of second projected electrodes each having a second center disposed on a second line linking the second centers, wherein:
the first line and the second line are laterally spaced apart;
a width of each first projected electrode is smaller than a width of each second projected electrode; and
a length of each first projected electrode is longer than a length of each second projected electrode.

6. Electronic equipment comprising:
a semiconductor chip;
a wiring board including a wiring pattern electrically connected to the semiconductor chip;
an electronic component electrically connected to the semiconductor chip through the wiring board;
a first projected electrode array disposed between the semiconductor chip and the wiring board, the first projected electrode array including a plurality of first projected electrodes each having a first center disposed on a first line linking the first centers; and
a second projected electrode array disposed between the semiconductor chip and the wiring board, the second projected electrode array including a plurality of second projected electrodes each having a second center disposed on a second line linking the second centers, wherein:
the first line and the second line are laterally spaced apart;
a width of each first projected electrode is smaller than a width of each second projected electrode; and
a length of each first projected electrode is longer than a length of each second projected electrode.

7. A method of manufacturing a semiconductor device that includes first and second projected electrode arrays projecting from and disposed on a semiconductor chip, the method comprising:
providing the first projected electrode array by disposing a plurality of first projected electrodes on the semiconductor chip, each first projected electrode having a first center disposed on a first line linking the first centers;
providing the second projected electrode array by disposing a plurality of second projected electrodes on the semiconductor chip, each second projected electrode having a second center disposed on a second line linking the second centers;
mounting the semiconductor chip on a wiring board where a wiring pattern is disposed through the first and second projected electrode arrays; and
electrically connecting the wiring pattern to the first and the second projected electrode arrays;
wherein a width of each first projected electrode is smaller than a width of each second projected electrode and a length of each first projected electrode is longer than a length of each second projected electrode.
